(19) United States
(12) Patent Application Publication
(10) Pub. No.: US 2016/0370425 A1
(43) Pub. Date: Dec. 22, 2016

(54) Particle Beam Heating to Identify Defects

(71) Applicant: DCG Systems, Inc., Fremont, CA (US)

(72) Inventors: Richard Stallcup, Frisco, TX (US); Vladimir Ukraintsev, Allen, TX (US); Mike Berkmyre, Allen, TX (US); Theodore Lundquist, Milpitas, CA (US)

(73) Assignee: DCG Systems, Inc., Fremont, CA (US)

(21) Appl. No.: 15/075,145

(22) Filed: Mar. 19, 2016

Related U.S. Application Data
(60) Provisional application No. 62/135,689, filed on Mar. 19, 2015.

(51) Int. Cl. G01R 31/307; G01R 31/303; G01R 1/30

(52) U.S. Cl. CPC G01R 31/307; G01R 1/30; G01R 31/303

(57) ABSTRACT

A charged particle beam, such as an electron beam or an ion beam, scans a device while a signal is applied to the device. As the particle beam scans, it locally heats the device, altering the local electrical characteristics of the device. The change in electrical characteristic is detected to and correlated to the position of the electron beam to localize a defect.

### TECHNICAL FIELD OF THE INVENTION

The present invention relates to fault analysis in integrated circuits and more specifically, to identifying and determining the location of resistive interconnect faults.

### BACKGROUND OF THE INVENTION

Defect identification and localization refers to determining the existence of a defect and pinpointing its location within an integrated circuit. Various techniques have been developed for defect identification and localization. Some techniques rely on the fact that thermal characteristics of a defective circuit region can differ from the thermal characteristics of defect-free circuit. By scanning a laser to locally heat a small region of the circuit, and monitoring some characteristic of the circuit, the change in the characteristic can be correlated to the position of the laser in its scan, thereby determining the location of the defect. Several scanning laser-based thermal techniques have been used to localize defects.

For example, in Optical Beam-Induced Resistance Change (OBIRCH), a constant voltage is applied to the circuit while the current is monitored during the laser scan. Some change in current is expected from the heating as the laser scans and heats different points of the circuit, but an abnormal change in current may indicate a defect at that scan position. A large change in current can be caused, for example, by a void or an open metal line which impedes the heat dissipation from that spot. By correlating the laser position in the scan with the change in current, the position of the defect can be found.

In a similar technique, Thermally-Induced Voltage Alteration (TIVA), a constant current source is applied to the circuit. Localized heating by the scanning laser increases the resistivity of shorts, resulting in increased power consumption. The location of the short is determined by correlating the position of the scanning laser when the power consumption changed.

Various optical probing techniques for fault localization are described in, for example, U.S. Pat. No. 6,444,895 for “Irradiation surfaces with laser beams; nondeforming detection of defects;” U.S. Pat. No. 6,549,022 for “Apparatus and method for analyzing functional failures in integrated circuits;” U.S. Pat. No. 6,593,156 for “Non-destructive inspection method;” U.S. Pat. No. 7,062,399 for “Resistivity analysis;” and U.S. Pat. No. 7,825,673 for “Failure analysis method and failure analysis apparatus.”

As described in U.S. Pat. No. 6,444,895, the lasers used typically have a wavelength longer than 1100 nm because such lasers are capable of transmitting through silicon material used in semiconductor substrates and heating metal wires. The lateral resolution of laser-based techniques is limited by the spot size of the laser, which is limited by its wavelength. The laser spot size is typically about one micron in diameter, which can cover about 10 to 50 interconnect elements. Also, in the time required to measure a scan point, the heat from the laser can spread several microns from the point of incidence of the beam. This thermal diffusion further limits the lateral resolution of optical techniques. The resolution of laser-based defect localization processes reduces their usefulness in modern integrated circuits.

Several techniques are utilized to improve the signal-to-noise ratio (SNR) of the OBIRCH and TIVA measurement. Such techniques include using a lock-in amplifier, as described in U.S. Pat. No. 7,825,673 for “Failure analysis method and failure analysis apparatus.” If the laser beam is pulsed, a lock-in amplifier can be used to improve the SNR at the pulse frequency. Another technique uses a highly sensitive magnetic field detector, such as a Superconducting Quantum Interference Device (SQUID), for detecting small changes in current by detecting small changes in the magnetic field caused by the current. Such a technique is described in U.S. Pat. No. 6,444,895 for a “Device and method for nondestructive inspection on semiconductor device.”

Another class of defect localization techniques uses an electron beam as a probe rather than a laser. The electron beam injects charges into the integrated circuit, and the flow of those charges, which is altered by the presence of defect, is detected to locate the defect. Unlike thermal techniques, which can a test signal can be applied to the circuit and a change in the test signal caused by local laser heating of the circuit can be detected, the detectable change in electron beam techniques is limited to the amount of current injected by the electron beam. The depth of penetration of an electron beam into a sample depends on the energy of the electrons in the beam and so level of interconnect at which the electrons are absorbed can be controlled to some extent.

One electron beam technique, Resistive Contrast Imaging (RCI) uses an electron beam having sufficient energy that the interaction volume, that is, the region in which electrons from the beam scatter within the sample, reaches the buried layer of interest, thereby injecting charges into the circuit at the desired layer. The injected electrons create a current between the injection point and test nodes. RCI requires two probes, one on each end of the circuit being tested. As the electron beam is scanned across the surface, the currents at the test nodes are measured to make a resistance map of the conductors. RCI is a differential technique that indicates a change in the direction or magnitude of the absorbed electron beam current. Because the differential current is relatively small, the signal amplifier must have a large gain, typically between 10⁹ and 10¹¹.

Biased RCI (BRCI) is similar to RCI, but the circuit is biased during testing. The bias is used to increase the observable signal contrast while doing RCI to detect opens. When the circuit is biased, the resistance difference becomes a logic map. The BRCI image of the device under test is compared to a BRCI image of a known good device, and the difference indicates the location of a defect.

RCI and BRCI are both used to detect resistive junctions in conductors. RCI and BRCI techniques measure the direction and magnitude of the absorbed electron beam current as the electron beam is scanned across the conductive elements that include the resistive junctions. With BRCI, since the scanning electron beam current that is absorbed by the faulty circuit is the signal of importance, the bias voltage across the faulty circuit needs to be low enough so that it does not cause a flow of current on its own that is more significant than the absorbed electron beam current. RCI and BRCI therefore suffer from poor signal-to-noise ratio for ICs having higher current consumption. Because the electron beam penetrates through passivation layers and other layers of conductors to inject charges into subsurface conductors, RCI and BRCI do not require removing layers to expose the conductor layer being tested. The energetic electrons can, however, damage the circuit.

Charge-Induced Voltage Alteration (CIVA), described in E. I. Cole, Jr. and R. E. Anderson, “Rapid Localization of IC Open Conductors Using Charge-Induced Voltage Alternation,” Proceedings of the 1992 IRPS (IEEE, 1992), was devised to overcome the sensitivity limitation of BRCI. In an active CMOS device, quantum tunneling may allow a circuit with an open conductor to function at low clock speeds. CIVA scans an electron beam to inject charges into subsurface conductors. When electrons are injected into non-failing conductors, the additional current, on the order of nanoamps, is readily absorbed and produces little change in the power supply voltage. If an open, floating conductor is operating in tunneling mode, however the injected charge produces additional loading on a constant current power supply, causing a detectable change in power consumption. CIVA is therefore used to identify opens as the electron beam modifies the potential on an interconnect feature that is completely disconnected from the rest of the IC.

The change in power consumption can be displayed on an SEM image of the device at the beam coordinates where the change was detected to show the floating conductors superimposed over the SEM image. Injecting charge through the passivation layer and directly into the subsurface layer requires a high energy electron beam, typically greater than 5 keV and often 10 keV or greater. The high energy beam can damage the integrated circuit.

Low Energy CIVA (LECIVA), as described in U.S. Pat. No. 5,523,694 for “Integrated circuit failure analysis by low-energy charge-induced voltage alteration,” was developed to avoid the radiation damage caused by the high energy, high current beam required in CIVA. LECIVA uses an electron beam having insufficient energy to inject charged directly into the interconnect layer below the passivation layer. The energy is typically about 0.3 keV to 1 keV and the current is relatively high, on the order of a few tens of nanoamps. In LECIVA, the scanning low-energy, high-current electron beam changes the electrical potential at the device surface, which electrostatically induces a small voltage pulse on the buried electrical conductor. The voltage pulse changes the voltage output of a constant-current power supply and the voltage signal can be displayed on an SEM image of the circuit.

Both CIVA and LECIVA utilize a constant-current source, the operating voltage of which changes in response to the charge on open interconnect elements caused by a focused electron beam directly (CIVA) or indirectly (LECIVA) through electrostatic coupling. In both cases (CIVA and LECIVA) open-circuit defects are identified and mapped as the focused electron beam is scanned over an operating IC or sub-region thereof.

CIVA relies on the full system power-up of the device. In CIVA and LECIVA the entire integrated device is powered and the faulty part of the circuit in the form of an open or isolated conductor is readily altered by the scanning electron beam as it penetrates into the circuit or charges nearby surfaces. Since the faulty conductor is isolated in the form of an open circuit, the electron beam directly or indirectly changes the potential of the faulty conductor thereby causing the entire integrated circuit to operate differently. This change is detected as a change in operational power consumption and is correlated with the momentary location of the scanning electron beam.

Another technique, Electron-Beam-Absorbed Current (EBAC) uses a wide range of electron beam energies and currents to visualize defects in interconnect lines. EBAC can detect both surface defects and defects buried under a dielectric. The beam energy controls the penetration of the beam and therefore the depth at which the current is injected. Measurements of current collected using a nanoprobe on a surface conductor are synchronized with the SEM raster to show the line opens and other interconnect elements shorted to the line. EBAC techniques measure the electron beam current that is absorbed into the IC. In some implementations, a voltage is applied only to help direct the absorbed electron beam current.

Each of these techniques has its limitations. In CIVA, the current that is monitored is the current that is flowing through the whole integrated circuit and not just the current that is flowing through a few pathways which include the defective conductive pathways of the integrated circuits. CIVA requires a functional integrated circuit for operation. EBAC does not require forcing a test current through a faulty junction—EBAC detects the current of charges injected by the electron beam. Neither CIVA nor EBAC can localize resistive opens or resistive shorts because the charge or absorbed current leaks out of the resistive interconnect feature, since the defect is not completely open. EBAC is also insensitive to resistive faults because EBAC electric loop has a very high effective resistance, typically between about 10⁶Ω and 10¹³Ω. In both RCI and EBAC, the absorbed electron beam current is the only signal that is monitored.

A technique that provides high lateral resolution and that is capable of detecting resistive defects is needed.

### SUMMARY OF THE INVENTION

An object of the invention is to provide a system for identifying and localizing a defect in an integrated circuit.

A charged particle beam, such as an electron beam or an ion beam, scans a device while a test signal is applied to the device. As the particle beam scans, it locally heats the device, altering the local electrical characteristics of the device. The change in electrical characteristic is detected by a change in the test signal and correlated to the position of the charged particle beam to localize a defect.

The foregoing has outlined rather broadly the features and technical advantages of the present invention in order that the detailed description of the invention that follows may be better understood. Additional features and advantages of the invention will be described hereinafter. It should be appreciated by those skilled in the art that the conception and specific embodiments disclosed may be readily utilized as a basis for modifying or designing other structures for carrying out the same purposes of the present invention. It should also be realized by those skilled in the art that such equivalent constructions do not depart from the scope of the invention as set forth in the appended claims.

### BRIEF DESCRIPTION OF THE DRAWINGS

For a more thorough understanding of the present invention, and advantages thereof, reference is now made to the following descriptions taken in conjunction with the accompanying drawings, in which:

FIG. 1 is a flow chart showing a method of defect identification and location.

FIG. 2 shows schematically an electron beam system for carrying out defect identification and location.

FIG. 3 shows schematically front side EBIRCH with use of microprobes or nano-probes for applying an electrical signal to the DUT.

FIG. 4 shows schematically backside EBIRCH with use of probe card for applying an electrical signal to the DUT.

FIG. 5 shows schematically identification and location of resistive metal line defect using EBIRCH

FIG. 6A shows the identification and localization of a line-to-line resistive short using EBIRCH. FIG. 6B shows the short in an EBIRCH image.

FIG. 7 shows schematically identification and location of a resistive line to via defect using EBIRCH

FIG. 8 is a superposition of an SEM image and an EBIRCH image showing defect in 50 nm metal line.

FIG. 9 shows schematically front side EBIRCH with using a SQUID magnetic sensor for EBIRCH current detection.

### DETAILED DESCRIPTION OF PREFERRED EMBODIMENTS

Charged particle beam induced resistivity change (CPBIRCH) is used to identify resistive defects, that is, resistive shorts and resistive opens, of conductive pathways. Resistive defects are defined as defects having a resistivity of between about 10Ω and about 10⁶Ω. A resistive defect can be, for example, a resistive current path where no current was intended, or a resistive current path, where a highly conductive current path was intended. As used herein, a resistive defect can include a defect having an impedance that includes a resistive aspect, and measuring resistance can include measuring impedance. CPBIRCH uses a relatively large test current flowing through the circuit path that includes the fault. In CPBIRCH, an electrical signal is applied to a circuit to provide a test current while the circuit is scanned by a charged particle beam, such as an electron beam for Electron Beam-Induced Resistivity Change (EBIRCH) or an ion beam for Ion Beam-Induced Resistivity Change (IBIRCH). The charged particle beam probe locally heats the circuit where it impacts. The description below is directed primary to EBIRCH, but a skilled person can adapt the techniques described to IBIRCH from a basic knowledge of the differences between how electron beams and ion beam react upon impacting a sample. In EBIRCH, the primary effect of the beam comes from locally heating the resistive defect, and not from injecting charge. The local heating provides a large change in the test current, which is change is typically much greater than the current in the electron beam.

In EBIRCH, an electrical signal is applied to a circuit to provide a test current while the circuit is scanned by an electron beam probe. The electron beam probe locally heats the circuit where it impacts. In prior electron beam techniques such as CIVA and EBAC, the injected charge is detected. In EBIRCH, the change in the resistive defect caused by heat is detected. The change in current caused by heating the resistive defect is typically greater than the charge injected. The test current that is forced through the conductive pathway of the faulty junction is typically greater than the electron beam current, typically more than 10 times greater, more typically more than 100 times greater, and often from 1,000 to 100,000 times greater than the electron beam current.

Unlike CIVA and EBAC, which identify a faulty interconnect feature that is completely open, that is, completely disconnected from the rest of the IC, EBIRCH can identify resistive shorts and opens in which the interconnect feature is not completely disconnected from the rest of the IC. The electron beam in EBIRCH can be focused to a much smaller spot than the laser beam of OBIRCH, thereby improvising lateral resolution.

CIVA requires some functionality of the entire integrated circuit. EBIRCH does not require any active devices. EBIRCH only needs two passive conductive materials that include a resistive junction that connect the two conductive materials. EBIRCH can be performed on any conductors connected by a resistive region and therefore can be performed on a portion of a circuit and even, for example, on a conductive layer after the silicon has been removed. A complete working circuit is not required.

Placement of the electrical probes in EBIRCH preferably isolates the path of the test current to exclude most of the integrated circuit. EBIRCH relies on a locally injected test current that can flow through many interconnects but the faulty interconnect is required to be in the test current path. Preferably all the test current flows through the resistive defect. In EBIRCH, electrons from the beam thermally heat a resistive defect to produce a significant resistance change. By applying a voltage to force current through this path, the change in resistance is observable as a change in the forced current. A focused electron beam having a spot size on the sample of several nanometers in diameter can localize the defect with high lateral resolution. In some cases, the output (current, voltage, power or impedance) of a power supply is monitored, and the change in power supply output is amplified to become the EBIRCH signal. Because the EBIRCH signal is derived from heating the defect and EBIRCH does not depend on detecting charge absorbed from the beam, the ratio of beam absorbed current to test current does not control the SNR, allowing for resistive defects to be detected. Because the change in test current caused by the heating is relatively large, the gain required for the amplification of the change in test current is typically less than 10⁶, more typically less than 10⁵ between about 10³ and 10⁴. The amplifier gain is typically more than 1,000 or 10,000 times smaller than the gain required of techniques, such as RCI, in which the signal measured is related to the electron beam absorbed current.

Further, as the electron beam heating volume is small, the heat injected by the electron beam creates a significant temperature increase in a short period of time. This reduces the heat diffusion, which improves lateral resolution, and allows for shorter dwell times at each dwell point. Faster electron beam scans provide higher lateral resolution of EBIRCH. For example, during a dwell period of 0.1 μs per pixel, which is relatively fast SEM imaging, the calculated heat spread is on the order of 200 nm in SiO₂. In practice, the heat spread can be less considering dynamics of electron beam interaction with the defect. Since the electron beam spot size is smaller than an IC feature size, EBIRCH resolution is essentially limited by the thermal diffusion of heat from the nanometer size electron beam interaction volume. Of course, faster electron beam scanning provides even greater improvement to lateral resolution. Preferred scan patterns can include, for example, dwell times ranging from about from 10 μs to 500 μs pixel sizes ranging from about a nanometer to about 500 nm The energy deposited by the electron beam per unit of time can be varied by varying the electron beam current and the electron beam landing energy. The landing energy also controls the penetration depth of the electron beam.

Novel scan patterns, such as patterns in which the pixels are not contiguous, could improve resolution. Pulsing of the electron beam can further decrease the thermal spreading as well as provide a time varying signal where lock-in techniques can be employed to improve the SNR.

Table 1 below shows a comparison of typical OBIRCH and EBIRCH process parameters. The electron beam power of common SEM systems is significantly lower than the power of lasers common used in OBIRCH system. The electron beam in EBIRCH therefore deposits significantly less energy into the IC in a given time period than the laser beam of OBIRCH deposits. Applicants have surprisingly found, however, that the energy from the electron beam is sufficient to heat a resistive defect sufficiently to a detectable change in the test current. The electron beam energy, while significantly smaller than the laser energy, is deposited into a significantly smaller volume, which provides very localized heating. Applicants have found that the deposited energy density (energy/volume), which determines the local (defect) temperature rise, is comparable for EBIRCH and OBIRCH cases. Moreover, while the OBIRCH laser wavelength is chosen so the silicon substrate will be relatively transparent to the OBIRCH laser, the silicon and silicon compounds are not transparent to the electron beam. While metals in general have greater electron stopping power than silicon compounds, in an integrated circuit, energy is deposited in the silicon compounds before the buried metal layer is reached by the electrons. The selectivity between the metal and the dielectric of the energy distribution would be expected to be less with an electron beam than with a laser. Also, as metal lines in newer semiconductors get thinner, their thermal mass is lower and the lower energy in the electron beam is able to more rapidly increase the temperature of the conductor. OBIRCH is performed in atmosphere, where as EBIRCH or IBIRCH is performed in a vacuum.

More powerful electron beam tools are readily available and can be used for EBIRCH when the requirement arises.

TABLE 1

| | OBIRCH | EBIRCH |
|---|---|---|
| Beam Dwell Time per pixel | 2 μs to 30 μs | 0.1 μs to 1000 μs |
| Power | 100 mW | 3 μW |
| Energy/pixel | 0.2 μJ to 3 μJ | 0.3 pJ to 30 pJ |
| Pixel Size | 1 μm to 80 μm | .03 μm to 0.3 μm |
| Energy/volume | 0.8 pJ/μm³ to 6 × 10⁶ pJ/μm³ | 20 pJ/μm³ to 2 × 10⁶ pJ/μm³ |
| Image frame acquisition time | | 0.08 s to 8 s |
| Beam Current | NA | 1 nA to 5 nA |
| Electron Landing Energy | NA | 2 keV to 10 keV |
| Test Current Ranges (Forced | +/−100 μA to +/−100 mA | +/−1 μA to +/−1 mA |
| Voltage Mode) | | |
| Test Voltage Ranges | Forced Current Mode: 0 V to | Forced Current Mode: 0 V to 2 V |
| | 2 V | Forced Voltage Mode: 0 V to 20 V |
| | Forced Voltage Mode: 0 V to | |
| | 20 V | |

In a typical EBIRCH analysis on an IC, a constant current or constant voltage is applied to the whole IC or part of the IC or test structure as needed. The electron beam and the electrical probes can be applied to the front side of the circuit, or the circuit can be flipped over, and the electron beam applied to the backside of the circuit while the electrical probes can still be connected to the front side, through the use of a probe card. For front side electron beam stimulation, an electrical signal can be applied through the IC package contacts. Micro-probing or nano-probing of depackaged and delayered IC's can also be used to apply the needed electrical settings to an IC area under test. A sequential front side wafer level nano-probing can accomplish a failure analysis of resistive defects at each process step.

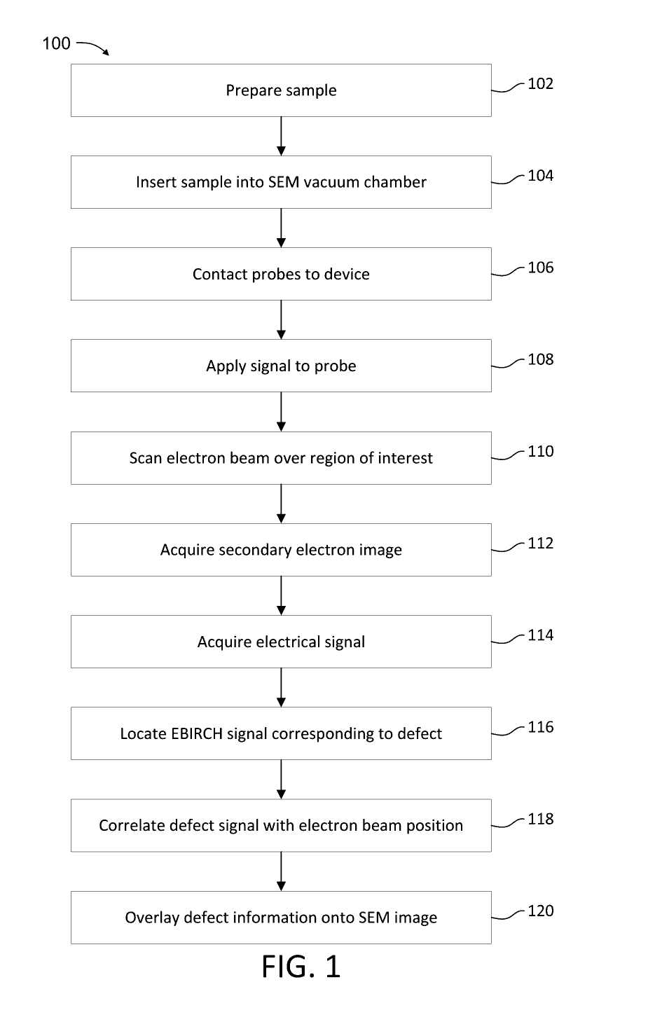

FIG. 1 is a flowchart 100 of a process using EBIRCH to localize a defect. The process can identify, for example, resistive shorts and resistive opens. In step 102, a sample is prepared. The preparation required depends on the sample and on the layer within the sample that is being probed. For example, an integrated circuit may be removed from its packaging and one or more layers removed as necessary to contact the required conductors. For probing a flip chip from the backside, the IC substrate can be thinned to about 100 nm level or the silicon substrate can be completely removed to access bottom levels of interconnect.

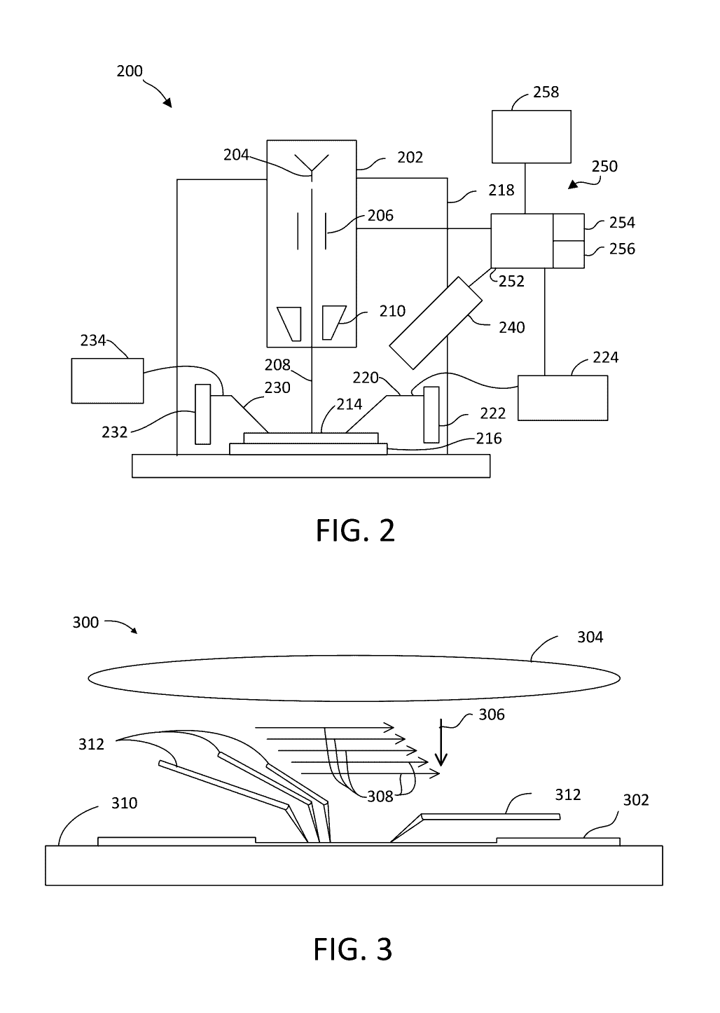

In step 104, the sample is inserted into the vacuum chamber of an electron beam system having multiple electrical probes. FIG. 2 shows schematically an electron beam system 200 that can be used to localize a defect using EBIRCH. Electron beam system 200 includes an electron focusing column 202 having an electron gun 204 for emitting electrons, deflectors 206 for positioning and scanning an electron beam 208, and an objective lens 210 for focusing the electron beam 208 onto spot on the sample 214 positioned on a moveable stage 216 within a vacuum chamber 218.

In step 106, one or more electrical probes make electrical contact with the conductor in the sample. FIG. 2 shows a first probe 220 that is manipulated by a probe positioner 222. First probe 220 is connected to a power supply 224 that can function as a current source or a voltage source. A second probe 230 is manipulated by a second probe positioner 232. Second probe 230 is connected to an amplifier 234 that can detect an electrical signal originating from first probe 220 and modified by the sample 214. Stage 216 can also be used to ground or apply a bias to sample 214.

In step 108, a signal is applied through first probe 220 to the circuit under test. The signal can be AC or DC and could be a voltage or a current. For example, a constant DC current power supply may apply a current to the circuit. In step 110, the electron beam 208 is scanned over the sample. The electron beam has a landing energy of about 3 keV and a current of about 1 nA to provide a power of 3 μW. The beam is scanned such that the dwell time at each pixel is between about 0.1 μs and about 10 μs. The pixel size, which is determined by the spot size of the beam, is between 0.03 μm and 0.3 μm. The energy per volume is therefore between 20 pJ/μm³ and 2×10⁶ pJ/μm³. An image of 1024×768 pixels therefore requires between 0.08 and 8 seconds to acquire.

As the electron beam scans, a secondary electron detector 240, such as an Everhart-Thornley detector, detects secondary electrons emitted from the sample 214 to acquire a secondary electron image in step 112. The signal from secondary electron detector 240 is processed by controller 250, which includes a processor 252, a program memory 254 for storing computer instructions and data memory 256. The secondary electron image is used to create an image of the sample on display 258.

As the electron beam is scanning, in step 114 an electrical signal is acquired. For example, the signal may be the output current, voltage, or power of power supply 224. As the electrons in the scanning beam impact a point on the sample, the electrons heat a resistive defect to produce a significant resistance change. By applying a voltage to force current through this path the change in resistance is evident in a change in the current. The change in current can be measured, or the change in voltage or power of a constant current power supply can be measure. The focused electron beam, having a spot size on the order of a several nanometers, can localize the resistive connection with high lateral resolution. This change in power supply output is amplified to become the EBIRCH signal. If an AC signal was applied, a change in impedance is measured caused by the heating is measured. This change may be due to a change in resistance, capacitance, or inductance of the defect.

In step 116, the EBIRCH signal is analyzed to find changes in the power supply that would indicate a defect. Such changes could include increases or decreases in the power supply power or voltage. In step 118, the location of defect is determined by the position of the electron beam in its scan when the defect was detected. In step 120, the defect location is overlaid onto the SEM image.

Sequential EBIRCH can be used to perform a failure analysis of resistive defects at each process step. The electrical signal can be applied to the device under test (DUT) using package contacts, micro-probing and nano-probing of depackaged and delayered IC's. FIG. 3 shows a configuration of a system 300 for locating a defect on a front side of a depackaged and delayered sample 302. Scanning electron microscope 304 produces an electron beam 306 which is rastered as indicated by arrows 308 across the sample positioned on an XYZ sample positioner 310. Probes 312 apply a signal to sample 302 and detect a change in the electrical characteristics of the sample. As shown in FIG. 3, EBIRCH can be done on top metal layers of original or delayered IC using front side electron beam stimulation.

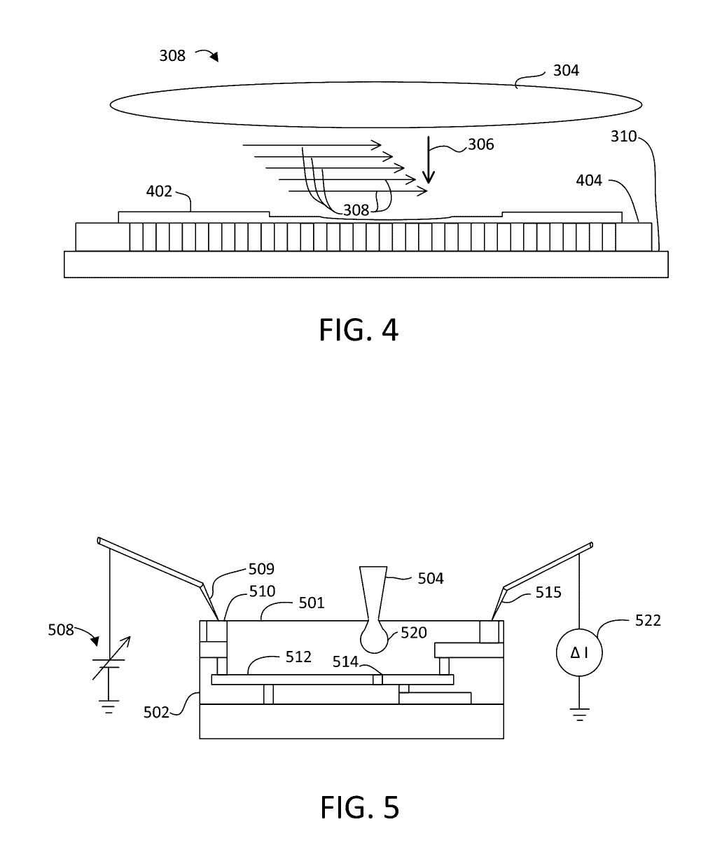

FIG. 4 shows a configuration for detecting resistive defects on the backside of an integrated circuit 402. In this configuration, the bottom layers of interconnect, such as M0, M1, etc., can be more readily accessed. Accessing the bottom layer of interconnects may require significant thinning, or even complete removal, of the silicon substrate. For example, the IC 402 substrate may be thinned to about 100 nm or the silicon is completely removed to access bottom levels of interconnect. The IC 402 is positioned upside down on a probe card 404 positioned on a sample positioner 310. Probe card 404 contacts the front side of upside down integrated circuit 402 to apply electrical signals to IC 402 while the electron beam 306 rasters across the backside.

FIG. 5 shows a system 500 for detecting a circuit defect on a sample 502. An electron beam 504 scans across an insulating region 501 of the sample 506 while a voltage is applied from a power supply 508 through a probe 509 to a surface conductor 510 that is in electrical contact with the buried conductor 512 having a resistive metal defect 514. A probe 515 completes the electrical circuit through the device, and the current through the circuit is measured at detector 522. As electron beam 504 impacts sample 502, the electrons are scattered in an interaction volume 520, which is shown not extending to resistive defect 514 indicating that the electrons in the beam are absorbed by the insulating material 501 before reaching conductor 512. The electron beam 504 heats the interaction volume, and the heat diffuses to heat up resistive defect 514, resulting in a change in current in current detector 522. While FIG. 5 shows current detector 522 in contact with probe 515, the signal could be measured at power supply 508.

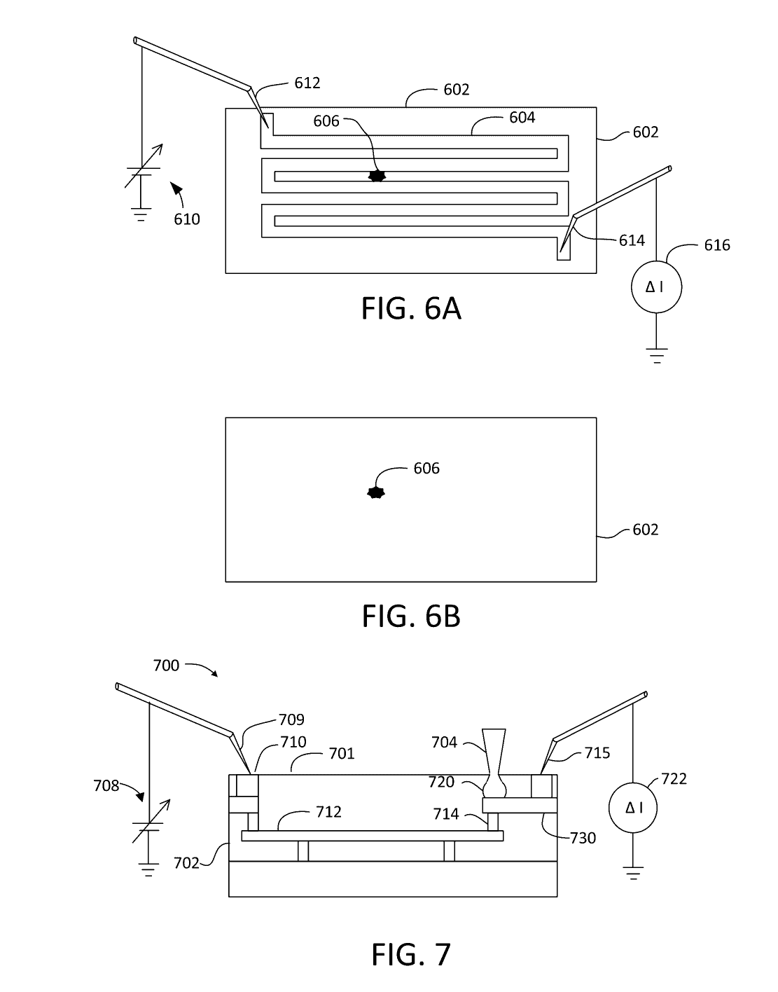

FIG. 6A shows a sample 602 having a serpentine conductor 604 with a resistive short 606 between two lines. A current from power supply 610 is applied through probe 612 and the circuit is completed through probe 614 which connects to a meter 616 that measures a change in current caused by heating of resistive short 606. As the electron beam scans sample 602, an image as shown in FIG. 6B is formed with the brightness pixels of the image corresponding to the change in current at the different points in the raster scan. The defect of FIG. 6B is then superimposed onto the SEM image in FIG. 6A.

FIG. 7 illustrates schematically a defect identification and localization system 700 using EBIRCH for detecting and localizing a circuit defect comprising a resistive line on a sample 702. An electron beam 704 scans across the surface of insulating region 701 of the sample 702 while a voltage is applied from a voltage supply 708 through a probe 709 to a conductor 710 that is in electrical contact with a resistive via 714. A probe 715 completes the electrical circuit through the device, and the current through the circuit is measured at detector 722. As electron beam 704 impacts sample 702, the electrons are scattered in an interaction volume 720, which is shown not extending to contact a conductor 730 above resistive defect 714. The electron beam 704 heats a portion of insulating region 701 and conductor 730. Also, charge will be injected into conductor 730. The amount of charge injected is relatively small, and the primary effect on the test current comes from the change in temperature of the resistive via 714 caused by the energy deposited by the electron beam.

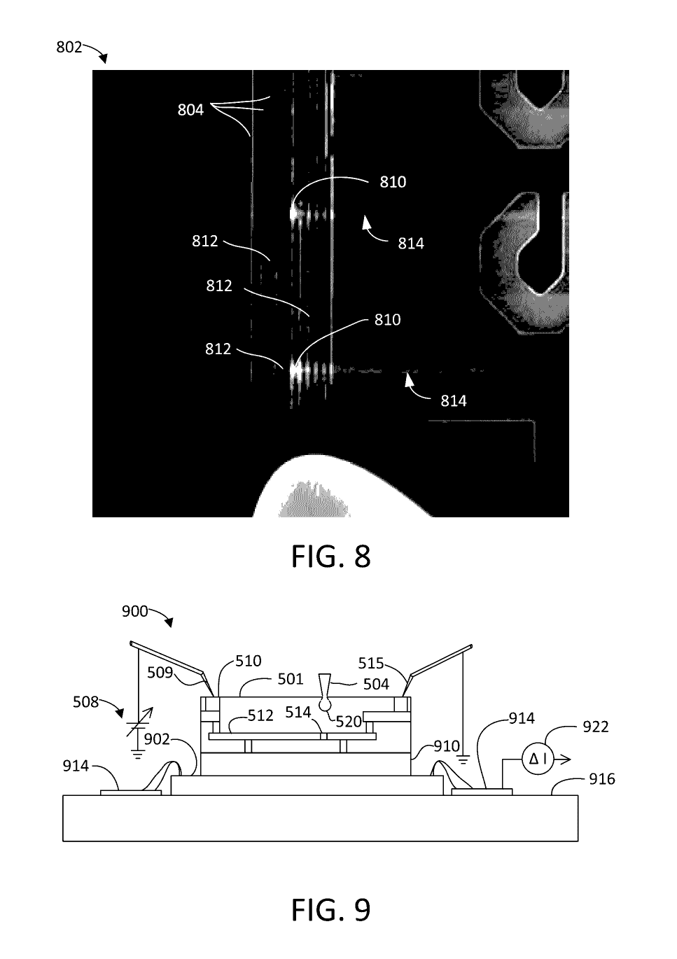

FIG. 8 is an image 802 showing an example of front side EBIRCH used to identify and localization a resistive defect in a 50 nm metal lines 804. Image 802 comprises an overlay of a secondary electron SEM grey-scale image and an EBIRCH gray-scale image. In the SEM image, the secondary electron current determines the brightness of each pixel—in the EBIRCH image, the change in current through the metal lines (at constant applied voltage) determines the brightness of each pixel, that is, lighter spots indicate elevated line resistance or/and reduced current. A nano-probe within the SEM vacuum chamber was contacted to the circuit to apply the test voltage.

FIG. 8 shows metal line defects 810 (shown as light features) located near dark, circular layout features 812. The horizontal smearing 814 of the light features representing defects may be caused by the limited bandwidth of the signal amplifier when the pixel dwell time is small or, when the pixel dwell time is large, the trace stays hot for time much greater than the pixel dwell time. EBIRCH signal can be positive (resistance increases with heating) or negative (resistance decreases with heating). In FIG. 8, the lighter regions 810 show positive EBIRCH signal for two spots on this image.

FIG. 9 shows a low noise EBIRCH implementation 900 using a SQUID magnetic sensor 902 to reduce noise. Elements of system 900 that are the same as those shown in FIG. 5 are shown with the same reference numbers. The IC is fabricated on a silicon substrate 910 which is mounted on SQUID sensor 902. SQUID sensor 902 can also be used in combination with electron beam pulsing and a lock-in amplification (not shown) to further improvement of signal-to-noise ratio. The output of the SQUID sensor is electrically connected to conductors 914, one of which is connected to a current meter. The SQUID amplifies the change in current as the electron beam scans the IC. The SQUID 902 and the e-beam 504 should be closely co-axial. Then the DUT would be on a stage and moved between these. The electrical output would not need to be on the stage. The stage z travel may not require z travel for the SQUID. The figure shows the IC stacked on top of the SQUID. The sample IC and SQUID would be moved together as one unit on the sample stage. The SQUID electrical output signal could be transmitted by conventional cables connected to the device or for convenience the SQUID could be connected to power via the nanoprobing system probes.

As shown above, EBIRCH is capable of detecting resistive line defects (FIG. 5), line to line resistive shorts (FIG. 6) and line to via resistive defects (FIG. 7). EBIRCH signal to noise ratio can be improved using modulated electron beam and lock-in amplifier, using a SQUID magnetic sensor for current measurements (FIG. 9) or any other methods known in the art. A lock-in amplifier is useful when the DUT is unstable. In that case, the electron beam is pulsed typically at a rate of between about 50 kHz and about 100 Hz using a beam blanker. The Lock-in amplifier operates at the same frequency as the beam blanker.

While the embodiments described above use an electron beam for local heating, an ion beam could also be used. Such implementations may be implemented in focused ion beam (FIB) or dual beam systems as well as with a helium or neon ion microscope. Using a plasma ion source allows for the use of a wide variety of ions. To reduce ion damage, lighter ions may be preferred.

Other electrical techniques can be used to defect resistance changes. For example, a variation of EBIRCH such as Electron Beam Induced Voltage Alternation or EBIVA, works similar to the way TIVA works, where high-current electron beam is used to modify thermally resistance of faulty pathways of IC.

Some embodiments of the invention provide a method of locating resistive defects in a circuit, comprising:

forcing a test current through a resistive defect in a circuit;

scanning a charged particle beam across a portion of the circuit including the resistive defect, the charged particle beam locally heating the circuit at the impact point;

detecting a change in resistivity of the resistive defect by detecting a change in the test current forced through the resistive defect as the resistive defect is heated by the charged particle beam; and

determining the position of the resistive defect from the position of the charged particle beam in its scan when the change in resistivity is detected.

In some embodiments, forcing the test current through a resistive defect in a circuit comprises forcing a test current that is greater in magnitude than the current of the electron beam.

In some embodiments, forcing the test current through a resistive defect comprises forcing a current between two electrical contact probes, with the entire test current passing through the resistive defect.

In some embodiments, forcing a current through a resistive defect in a circuit comprises forcing the current through a resistive defect in an unpowered integrated circuit.

In some embodiments, forcing a current through a resistive defect in a circuit comprises forcing the test current through only a portion of the circuit.

In some embodiments, detecting a change in the test current forced through the resistive defect includes detecting a change in the test current that is greater than 100 times the electron beam current.

In some embodiments, detecting a change in the test current forced through the resistive defect includes detecting a change in the test current that is between 1,000 and 100,000 greater than the electron beam current.

In some embodiments, the charged particle beam is an electron beam.

In some embodiments, forcing a current through a resistive defect in a circuit comprises contacting a probe to a conductor on an integrated circuit.

In some embodiments, determining the position of the resistive defect from the position of the charged particle beam in its scan when the change in resistivity is detected comprises forming a resistivity image representing the circuit in which the brightness of pixels of the resistivity image correspond to the change in resistivity at corresponding positions of the charged particle beam on the circuit.

Some embodiments further comprise detecting secondary or backscattered electrons as the electron beam scans the circuit to form an electron image of the circuit and further comprising superimposing the resistivity image onto the electron image.

Some embodiments further comprise overlaying superimposing a specific circuit feature or CAD coordinates onto the electron image.

In some embodiments, forcing a test current through a resistive defect in a circuit comprises applying a current from a constant current power supply and in which detecting a change in resistivity of the resistive defect by detecting a change in the power or voltage output of the constant current power supply.

In some embodiments, the electron beam comprises a current greater than 0.1 nA.

In some embodiments, the electron beam comprises a current of between 1 nA and 20 nA and the electrons in the beam have a landing energy of between 500 eV and 10,000 eV.

In some embodiments, the dwell time of the electron beam at each pixel is between 0.1 μs and 1,000 μs and the electron beam deposits energy of between 0.3 pJ to 30 pJ per pixel during each dwell period.

Some embodiments further comprise removing a passivation layer of the integrated circuit before directing the electron beam towards the integrated circuit.

In some embodiments, scanning an electron beam across a portion of the integrated circuit includes directing an electron beam to impact an insulating layer over the resistive fault.

In some embodiments, the electron beam is characterized by an interaction volume and in which scanning an electron beam across a portion of a circuit includes scanning an electron beam such that the interaction volume does not contact the resistive defect.

In some embodiments, the electron beam is characterized by an interaction volume and in which scanning an electron beam across a portion of a circuit includes scanning an electron beam such that the interaction volume contacts the resistive defect.

In some embodiments forcing a current through a resistive defect in a circuit includes applying an AC voltage to the circuit; and detecting a change in the electrical properties of the defect comprises detecting a change in impedance of the circuit as the defect is heated by the electron beam.

In some embodiments forcing a current through a resistive defect in a circuit includes applying an DC voltage to the circuit; and detecting a change in the electrical properties of the defect comprises by detecting a change in resistivity.

In some embodiments, detecting a change in the test current forced through the resistive defect comprises amplifying a change in the test signal by a factor of less than 10⁶.

In some embodiments, amplifying a change in the test signal by a factor of less than 10⁶ comprises amplifying a change in the test signal by between 10³ and 10⁴.

In some embodiments, scanning a charged particle beam across a portion of the circuit includes pulsing the electron beam and in which detecting a change in the test current forced through the resistive defect includes using a lock-in amplifier.

In some embodiments, detecting a change in the test current forced through the resistive defect includes using a SQUID.

Some embodiments provide a system for determining a fault in a circuit, comprising:

a charged particle source;

a charged particle column for focusing the charged particle beam onto a circuit in a vacuum chamber;

a signal source for forcing a current through a portion of the integrated circuit;

a sensor for detecting a change in the current as the charged particle beam is scanned over the integrated circuit; and

a processor for controlling the system to perform one or more of the steps of any of the methods described above.

In some embodiments, the charged particle source comprises an electron source.

In some embodiments, the charged particle source comprises an ion source.

In some embodiments, the sensor includes an amplifier having a gain of less than 10⁶.

In some embodiments, the amplifier has a gain of less than 10⁴.

In some embodiments, the amplifier comprises a SQUID or a lock-in amplifier.

The methods described herein can be applied manually or can be automated and some or all of the steps can be performed under computer control.

A preferred method or apparatus of the present invention has many novel aspects, and because the invention can be embodied in different methods or apparatuses for different purposes, not every aspect need be present in every embodiment. Moreover, many of the aspects of the described embodiments may be separately patentable. The invention has broad applicability and can provide many benefits as described and shown in the examples above. The embodiments will vary greatly depending upon the specific application, and not every embodiment will provide all of the benefits and meet all of the objectives that are achievable by the invention.

It should be recognized that embodiments of the present invention can be implemented via computer hardware, a combination of both hardware and software, or by computer instructions stored in a non-transitory computer-readable memory. The methods can be implemented in computer programs using standard programming techniques—including a non-transitory computer-readable storage medium configured with a computer program, where the storage medium so configured causes a computer to operate in a specific and predefined manner—according to the methods and figures described in this Specification. Each program may be implemented in a high level procedural or object oriented programming language to communicate with a computer system. However, the programs can be implemented in assembly or machine language, if desired. In any case, the language can be a compiled or interpreted language. Moreover, the program can run on dedicated integrated circuits programmed for that purpose.

Further, methodologies may be implemented in any type of computing platform, including but not limited to, personal computers, mini-computers, main-frames, workstations, networked or distributed computing environments, computer platforms separate, integral to, or in communication with charged particle tools or other imaging devices, and the like. Aspects of the present invention may be implemented in machine readable code stored on a non-transitory storage medium or device, whether removable or integral to the computing platform, such as a hard disc, optical read and/or write storage mediums, RAM, ROM, and the like, so that it is readable by a programmable computer, for configuring and operating the computer when the storage media or device is read by the computer to perform the procedures described herein. Moreover, machine-readable code, or portions thereof, may be transmitted over a wired or wireless network. The invention described herein includes these and other various types of non-transitory computer-readable storage media when such media contain instructions or programs for implementing the steps described above in conjunction with a microprocessor or other data processor. The invention also includes the computer itself when programmed according to the methods and techniques described herein.

Computer programs can be applied to input data to perform the functions described herein and thereby transform the input data to generate output data. The output information is applied to one or more output devices such as a display monitor. In preferred embodiments of the present invention, the transformed data represents physical and tangible objects, including producing a particular visual depiction of the physical and tangible objects on a display.

Although much of the previous description is directed at mineral samples from drill cuttings, the invention could be used to prepare samples of any suitable material. The terms “work piece,” “sample,” “substrate,” and “specimen” are used interchangeably in this application unless otherwise indicated. Further, whenever the terms “automatic,” “automated,” or similar terms are used herein, those terms will be understood to include manual initiation of the automatic or automated process or step.

In the following discussion and in the claims, the terms “including” and “comprising” are used in an open-ended fashion, and thus should be interpreted to mean “including, but not limited to . . . .” To the extent that any term is not specially defined in this specification, the intent is that the term is to be given its plain and ordinary meaning. The accompanying drawings are intended to aid in understanding the present invention and, unless otherwise indicated, are not drawn to scale.

The various features described herein may be used in any functional combination or sub-combination, and not merely those combinations described in the embodiments herein. As such, this disclosure should be interpreted as providing written description of any such combination or sub-combination.

Although the present invention and its advantages have been described in detail, it should be understood that various changes, substitutions and alterations can be made to the embodiments described herein without departing from the scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

1. A method of locating resistive defects in a circuit, comprising:
forcing a test current through a resistive defect in a circuit;
scanning a charged particle beam across a portion of the circuit including the resistive defect, the charged particle beam locally heating the circuit at the impact point;
detecting a change in resistivity of the resistive defect by detecting a change in the test current forced through the resistive defect as the resistive defect is heated by the charged particle beam; and
determining the position of the resistive defect from the position of the charged particle beam in its scan when the change in resistivity is detected.

2. The method of claim 1 in which forcing the test current through a resistive defect in a circuit comprises forcing a test current that is greater in magnitude than the current of the electron beam.

3. The method of claim 1 in which forcing the test current through a resistive defect comprises forcing a current between two electrical contact probes, with the entire test current passing through the resistive defect.

4. The method of claim 1 in which the forcing a current through a resistive defect in a circuit comprises forcing the test current through only a portion of the circuit.

5. The method of claim 1 in which detecting a change in the test current forced through the resistive defect includes detecting a change in the test current that is greater than 100 times the electron beam current.

6. The method of claim 1 in which the charged particle beam is an electron beam.

7. The method of claim 1 in which determining the position of the resistive defect from the position of the charged particle beam in its scan when the change in resistivity is detected comprises forming a resistivity image representing the circuit in which the brightness of pixels of the resistivity image correspond to the change in resistivity at corresponding positions of the charged particle beam on the circuit.

8. The method of claim 7 further comprising detecting secondary or backscattered electrons as the electron beam scans the circuit to form an electron image of the circuit and further comprising superimposing the resistivity image onto the electron image.

9. The method of claim 8 further comprising superimposing a specific circuit feature or CAD coordinates onto the electron image

10. The method of claim 1 in which forcing a test current through a resistive defect in a circuit comprises applying a current from a constant current power supply and in which detecting a change in resistivity of the resistive defect by detecting a change in the power or voltage output of the constant current power supply.

11. The method of claim 1 in which the electron beam comprises a current greater than 0.1 nA.

12. The method of claim 11 in which the electron beam comprises a current of between 1 nA and 20 nA and the electrons in the beam have a landing energy of between 500 eV and 10,000 eV.

13. The method of claim 1 in which the dwell time of the electron beam at each pixel is between 0.1 μs and 1,000 μs and the electron beam deposits energy of between 0.3 pJ to 30 pJ per pixel during each dwell period.

14. The method of claim 1 further comprising removing a passivation layer of the integrated circuit before directing the electron beam towards the integrated circuit.

15. The method of claim 1 in which the electron beam is characterized by an interaction volume and in which scanning an electron beam across a portion of a circuit includes scanning an electron beam such that the interaction volume contacts the resistive defect.

16. The method of claim 1 in which:
forcing a current through a resistive defect in a circuit includes applying an AC voltage to the circuit; and
detecting a change in the electrical properties of the defect comprises detecting a change in impedance of the circuit as the defect is heated by the electron beam.

17. The method of claim 1 in which:
forcing a current through a resistive defect in a circuit includes applying an DC voltage to the circuit; and
detecting a change in the electrical properties of the defect comprises by detecting a change in resistivity.

18. The method of claim 1 in which detecting a change in the test current forced through the resistive defect comprises amplifying a change in the test signal by between 10³ and 10⁴.

19. The method of claim 1 in which scanning a charged particle beam across a portion of the circuit includes pulsing the electron beam and in which detecting a change in the test current forced through the resistive defect includes using a lock-in amplifier.

20. A system for determining a fault in a circuit, comprising:
a charged particle source;
a charged particle column for focusing the charged particle beam onto a circuit in a vacuum chamber;
a signal source for forcing a current through a portion of the integrated circuit;
a sensor for detecting a change in the current as the charged particle beam is scanned over the integrated circuit; and
a system processor for controlling one or more aspects of the system, in which the system is configured to perform the steps of claim 1.

21. The system of claim 20 in which the charged particle source comprises an electron source or an ion source.

22. The system of claim 20 in which the sensor includes an amplifier having a gain of less than 10⁶.

23. The system of claim 20 in which the amplifier comprises a SQUID or a lock-in amplifier.
